(19) United States
(12) Patent Application Publication
(10) Pub. No.: US 2004/0116077 A1
(43) Pub. Date: Jun. 17, 2004

(54) Transmitter device and receiver device adopting space time transmit diversity multicarrier CDMA, and wireless communication system with the transmitter device and the receiver device

(75) Inventors: Kyesan Lee, Saitama (JP); Takeo Ohseki, Saitama (JP); Hiroyasu Ishikawa, Saitama (JP); Hideyuki Shinonaga, Saitama (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KDDI CORPORATION, Tokyo (JP)

(21) Appl. No.: 10/628,454

(22) Filed: Jul. 29, 2003

(30) Foreign Application Priority Data
Aug. 8, 2002 (JP) 2002-231144

(51) Int. Cl. H04B 1/02; H03C 7/02

(52) U.S. Cl. 455/101; 455/562.1

(57) ABSTRACT

A receiver device adopting STTD MC-CDMA scheme, includes a plurality of receive antennas, a plurality of MC-CDMA receive units for respectively converting received signals from the plurality of receive antennas into parallel signals, for respectively performing FFT of the converted parallel signals, for respectively inversely spreading transformed signals, and for respectively equalizing and combining inversely spread signals, STTD decoding units for decoding in time direction and in space direction output signals from the plurality of MC-CDMA receive units, a parallel to serial conversion unit for converting output signals from STTD decoding units into serial signals, a de-mapping unit for de-mapping output serial signals from the parallel to serial conversion unit, and a decoding de-interleaving unit for de-interleaving output signals from the de-mapping means and for decoding de-interleaved data by performing error correction.

### FIELD OF THE INVENTION

The present invention relates to multicarrier code division multiple access (MC-CDMA) transmitter device and receiver device, and to a wireless communication system with the transmitter device and the receiver device.

### DESCRIPTION OF THE RELATED ART

A high-rate wireless communication system is susceptible to a multipath fading and thus easy to decline in the quality of its wireless links. Therefore, an MC-CDMA scheme that has a high resistance against a multipath interference has been proposed to use in such high-rate wireless communication system. This MC-CDMA scheme is very effective for realizing a broadband radio access transmission.

However, since the MC-CDMA scheme does not provide a multipath-separation function performed by a RAKE receiver, which is an advantage of a spread spectrum method such as a direct sequence CDMA (DS-CDMA) scheme, no path-diversity effect can be expected in the MC-CDMA system in comparison with the DS-CDMA system resulting poor transmission performance. Also, in the MC-CDMA system, since data sequences are transmitted by copying the same symbol to a plurality of subcarriers, a frequency diversity effect can be expected. However, when there is a high correlation between the subcarriers, the frequency diversity effect may become poor.

### SUMMARY OF THE INVENTION

It is therefore an object of the present invention to provide MC-CDMA transmitter device and receiver device and a wireless communication system with the transmitter device and the receiver device, whereby improved transmission performance can be expected by adopting space time transmit diversity (STTD) scheme.

Another object of the present invention is to provide MC-CDMA transmitter device and receiver device and a wireless communication system with the transmitter device and the receiver device, which can be implemented by a small scale of hardware even when the number of subcarriers increases.

According to the present invention, a transmitter device adopting STTD MC-CDMA scheme, includes an encoding interleaving unit for encoding transmit data by performing error correction and for interleaving the encoded data, a mapping unit for mapping output signals from the encoding interleaving unit to signal points on a conjugate plane, a serial to parallel conversion unit for converting output signals from the mapping unit into Nc/SF parallel signals, where Nc is an integer representing the number of points of inverse fast Fourier transform (IFFT) and SF is an integer and a submultiple of Nc, Nc/SF STTD encoding unit for encoding in time direction and in space direction the parallel signals from the serial to parallel conversion unit, a plurality of MC-CDMA transmit units for respectively copying in parallel output signals from the Nc/SF STTD encoding unit to SF signals, for respectively spreading copied signals, for respectively performing IFFT of Nc points with respect to spread signals, and for respectively converting transformed parallel signals into serial signals, and a plurality of transmit antennas for respectively transmitting output signals from the plurality of MC-CDMA transmit units.

According to the present invention, also, a receiver device adopting STTD MC-CDMA scheme, includes a plurality of receive antennas, a plurality of MC-CDMA receive units for respectively converting received signals from the plurality of receive antennas into parallel signals, for respectively performing fast Fourier transform (FFT) of the converted parallel signals, for respectively inversely spreading transformed signals, and for respectively equalizing and combining inversely spread signals, STTD decoding units for decoding in time direction and in space direction output signals from the plurality of MC-CDMA receive units, a parallel to serial conversion unit for converting output signals from STTD decoding units into serial signals, a de-mapping unit for de-mapping output serial signals from the parallel to serial conversion unit, and a decoding de-interleaving unit for de-interleaving output signals from the de-mapping means and for decoding de-interleaved data by performing error correction.

Furthermore, according to the present invention, a wireless communication system includes the above-mentioned transmitter device and receiver device.

The transmitter device and a receiver device adopting STTD MC-CDMA scheme according to the present invention can simultaneously provide both frequency diversity effect by virtue of the MC-CDMA scheme and antenna diversity effect by virtue of the STTD scheme under multipath fading environment. Thus, according to the present invention, improved transmission performance and improved line quality in a radio channel can be expected and therefore a broadband wireless access transmission with a higher rate and better quality can be realized.

In other words, according to the present invention, since encoded data are transmitted in time direction and in space direction from a plurality of transmit antennas and the transmitted encoded data are decoded at the receiver side, it is possible to separate signals from the plurality of transmit antennas so as to obtain antenna diversity effect. In addition, since the frequency diversity effect by virtue of MC-CDMA is obtained, transmission performance can be improved even in a poor fading environment.

It is preferred that the plurality of MC-CDMA transmit units includes sections for adding guard intervals to the serial signals, respectively.

It is also preferred that each of the plurality of MC-CDMA transmit units includes Nc/SF copiers for respectively copying in parallel output signals from the Nc/SF STTD encoding units to SF signals, spreading sections for spreading Nc output signals from the Nc/SF copiers by multiplying spreading codes, an IFFT section for performing IFFT of Nc points with respect to output signals from the spreading sections, a parallel to serial conversion section for converting parallel signals from the IFFT section into a serial signal, and a section for adding a guard interval to the serial signal from the parallel to serial conversion section.

It is further preferred that the plurality of MC-CDMA receiver units includes sections for removing guard intervals from the received signals, respectively.

It is still further preferred that each of the plurality of MC-CDMA receiver units further includes a channel estimator for estimating channel for respective subcarriers, and equalizer and combiner sections for respectively equalizing and combining the inversely spread signals in accordance with estimated channels.

It is preferred that each of the plurality of MC-CDMA receiver units includes a guard interval removal section for removing a guard interval from the received signal, a serial to parallel conversion section for converting a serial signal from the guard interval removal section into parallel signals, a FFT section for performing FFT of the parallel signals from the serial to parallel conversion section, inverse spreading sections for inversely spreading transformed signals from the FFT section by multiplying spreading codes that are the same as spreading codes used in a transmitter device, a channel estimator for estimating channel for respective subcarriers, and equalizer and combiner sections for respectively equalizing and combining the inversely spread signals from the inverse spreading sections in accordance with estimated channels.

It is also preferred that each of the plurality of MC-CDMA receiver units further includes an estimated value combiner for combining channel estimated values from the channel estimator, and that the STTD decoding units decode output signals from the plurality of MC-CDMA receive units by using combined channel estimated values from the estimated value combiner. According to this feature, increase in hardware scale of STTD configuration due to increase in the number of subcarriers of MC-CDMA can be effectively suppressed. In general, the time-space decoding scheme requires channel estimation values and thus it is necessary to perform the time-space decoding for each estimated channel characteristics, that is, for each subcarrier. Whereas, according to the present invention, since after equalizing and combining, the signals are time-space decoded using channel estimation values that are combined by the same combining method as done in the equalizing and combining step, the hardware scale for the time-space decoding can be always maintained to 1/SF with respect to the conventional scale. Particularly, when the number of subcarriers is large, the above-mentioned configuration according to the present invention is extremely effective.

Preferably, the spreading codes are Walsh Hadamard codes.

Further objects and advantages of the present invention will be apparent from the following description of the preferred embodiments of the invention as illustrated in the accompanying drawings.

### BRIEF DESCRIPTION OF THE DRAWINGS

FIG. 1 shows a block diagram schematically illustrating a configuration of a transmitter device in a preferred embodiment according to the present invention;

FIG. 2 shows a block diagram schematically illustrating a configuration of a receiver device in the embodiment of FIG. 1;

FIG. 3 illustrates a principle of the STTD scheme; and

FIG. 4 shows a block diagram schematically illustrating a principle configuration of an STTD receiver device according to the present invention.

### DESCRIPTION OF THE PREFERRED EMBODIMENTS

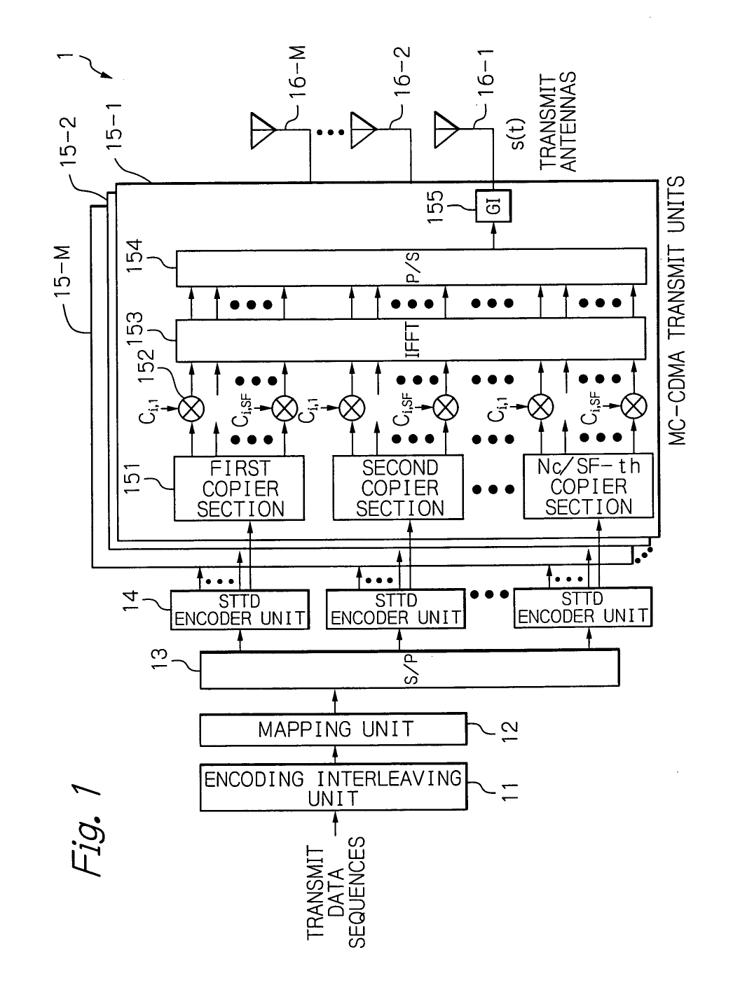

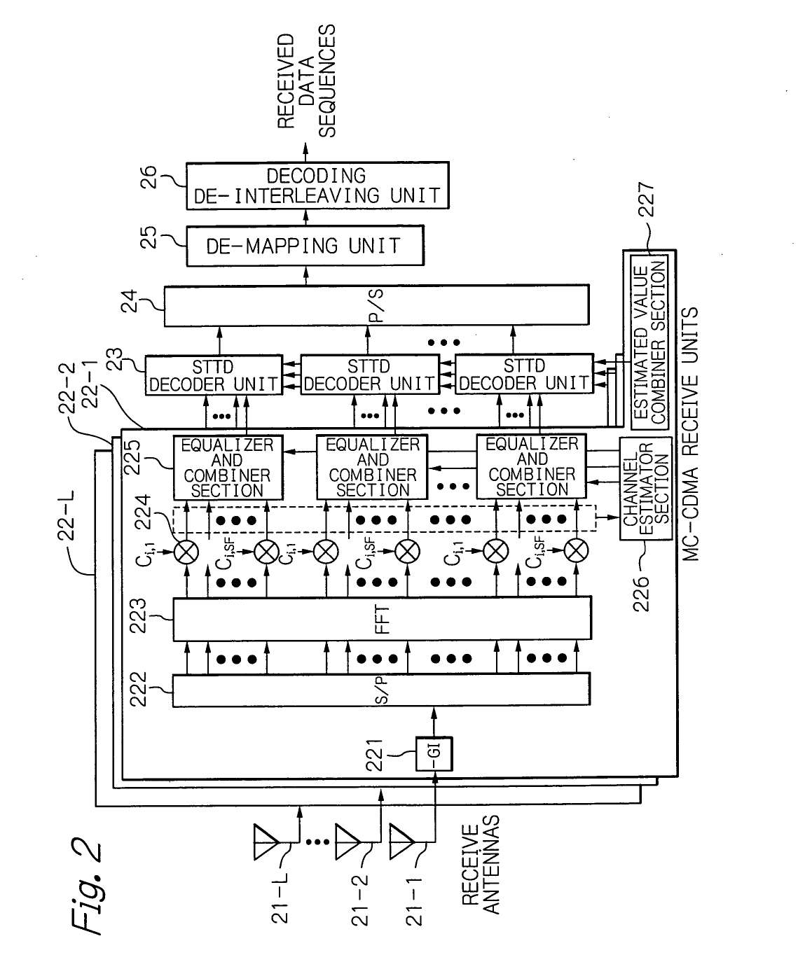

FIG. 1 schematically illustrates a configuration of a transmitter device in a preferred embodiment according to the present invention, and FIG. 2 schematically illustrates a configuration of a receiver device in the embodiment of FIG. 1.

In the instant invention, an STTD scheme is adopted in an MC-CDMA system. This STTD scheme is an anti-fading technique wherein a transmitter side transmits time-space encoded signals from a plurality of antennas and a receiver side separately receives signals from the plurality of antennas antenna and merges them to obtain antenna diversity effect. It should be noted however that the STTD scheme itself may yield poor antenna diversity effect causing BER performance to deteriorate under an environment in which a fading correlation between the antennas is high.

The transmitter device 1 has, as shown in FIG. 1, an encoding interleaving unit 11 that encodes by performing error correction transmit data sequence and interleaves the encoded data, a mapping unit 12, a serial to parallel (S/P) converter unit 13, Nc/SF STTD encoding (STTD encoder) units 14, M MC-CDMA transmit units 15-1 to 15-M, and M transmit antennas 16-1 to 16-M, where Nc is an integer representing the number of points of an IFFT section, SF is an integer and a submultiple of Nc, and M is an integer more than one.

Each of the MC-CDMA transmit units 15-1 to 15-M includes first to Nc/SF-th copier sections 151, spreading sections 152, the IFFT section 153, a parallel to serial (P/S) converter section 154 and a guard interval (GI) section 155.

Transmit data sequences input in this transmitter device 1 are encoded by performing error correction and interleaved at the encoding interleaving unit 12, and then mapped to signal points on a conjugate plane at the mapping unit 12.

The mapped signals from the mapping unit 12 are converted into Nc/SF parallel symbol sequences at the S/P converter unit 13.

The Nc/SF parallel symbol sequences from the S/P converter unit 13 are input into the STTD encoder units 14 by successive N symbols, respectively, where N is an integer more than one.

Each of the STTD encoder units 14 performs space-time coding with respect to the input signals of successive N symbols to produce output signals of N symbols in time direction and M symbols in space direction.

The M symbols in space direction from each of the STTD encoder units 14 are input into the MC-CDMA transmit units 15-1 to 15-M, respectively.

In each of the MC-CDMA transmit units 15-1 to 15-M, the input parallel data sequences are input into the first to Nc/SF-th copier sections 151, respectively, and copied to SF parallel signals at each copier section.

Then, at the spreading sections 152, the output from the first to Nc/SF-th copier sections 151 are multiplied by spreading codes Cᵢ₁, Cᵢ₂, . . . , C_{iSF} (Cᵢⱼ∈{−1, 1}), respectively. The spreading codes may be for example the Hadamard Walsh codes.

Then, at the IFFT section 153 of Nc points, the spread signals are transformed into values at the respective sample points in the time domain.

Then, the transformed signals are parallel to serial converted at the P/S converter section 154, and then a guard interval is added to the converted serial signals at the GI section 155. Thereafter, the outputs from the MC-CDMA transmit units 15-1 to 15-M are simultaneously transmitted from the transmit antennas 16-1 to 16-M, respectively. The guard interval is added to the transmitted signals in order to avoid intersymbol interference due to the delayed wave.

The receiver device 2 has, as shown in FIG. 2, L receive antennas 21-1 to 21-L, L MC-CDMA receive units 22-1 to 22-L. Nc/SF STTD decoding (STTD decoder) units 23, a parallel to serial (P/S) converter unit 24, a de-mapping unit 25 and a decoding de-interleaving unit 26, where L is an integer more than one, Nc is an integer representing the number of points of a FFT section, and SF is an integer and a submultiple of Nc.

Each of the MC-CDMA receive units 22-1 to 22-L includes a guard interval removal (−GI) section 221, a parallel to serial (P/S) converter section 222, the FFT section 223, inverse spreading sections 224, equalizer and combiner sections 225, a channel estimator section 226 and an estimated value combiner section 227.

Received signals from the receive antennas 21-1 to 21-L in this receiver device 2 are input into the MC-CDMA receive units 22-1 to 22-L, respectively.

In each of the MC-CDMA receive units 22-1 to 22-L, a guard interval is removed from the received signal at the −GI section 221, and then the GI-removed signal is converted into Nc parallel signals at the S/P converter section 222.

Then, at the FFT section 223 of Nc points, the parallel signals are transformed into signals at the respective subcarriers in the frequency domain.

Then, at the inverse spreading sections 224, the transformed signals for SF subcarriers from the FFT section 223 are multiplied by spreading codes, respectively. The spreading codes are the same codes Cᵢ₁, Cᵢ₂, . . . , C_{iSF} (Cᵢⱼ∈{−1, 1}) used in the transmitter device 1.

At the equalizer and combiner sections 225, inverse spread signals for the respective subcarriers are equalized by using channel estimated values for the respective subcarriers, and then SF equalized signals are combined. In combining, an optional combining scheme such as an equal gain combining method or a minimum mean square error combining (MMSEC) method can be adopted.

The channel estimated values for the respective subcarriers are estimated at the channel estimator section 226 based upon known signals such as preamble signals attached to a top of the transmitted frame or pilot subcarriers inserted between the data subcarriers. The channel estimated values for the respective subcarriers from the channel estimator section 226 are combined at the estimated value combiner section 227 using the same unit (SF) and the same combining scheme as done in the equalizer and combiner sections 225. The combined estimated value is applied to the STTD decoder units 23.

The parallel signals from the equalizer and combiner sections 225 in the L MC-CDMA receive units 22-1 to 22-L are input into the STTD decoder units 23. In the STTD decoder units 23, STTD decoding of the input parallel signals of L symbols in space direction and N symbols in time direction is performed using channel estimated values from the respective combiners 226 of the MC-CDMA receive units 22-1 to 22-L and serial data of N symbols in time direction are output.

The output data from the STTD decoder units 23 are at parallel to serial converted at the P/S converter unit 24, and then all symbols thereof are demodulated at the de-mapping unit 25. Thereafter, the de-mapped data are de-interleaved and decoded by performing error correction to provide received data sequences at the decoding de-interleaving unit 26.

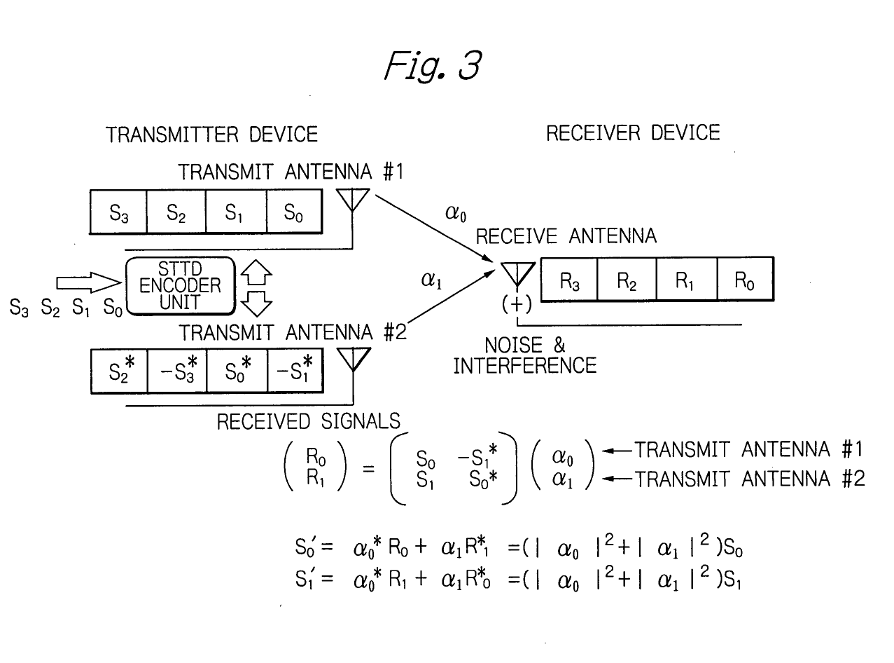

FIG. 3 illustrates a principle of the STTD scheme in case of N=2, M=2 and L=1, where “*” represents complex conjugate operation. Hereinafter, the STTD principle will be described with respect to a simple model of this condition.

A typical transmit diversity is accepted as a closed loop antenna diversity that uses feedback information for performing antenna selection and phase control. However, the instant invention adopts an open loop transmit diversity that uses no feedback information and includes a transmitter for transmitting signals via a plurality of antennas, and a receiver for separating a received signal and finally combining the separated signals.

As shown in FIG. 3, data input into the STTD encoder unit is processed in a unit of two symbols. During a given symbol period, a signal S₀ is transmitted from a transmit antenna #1 and a signal −S₁* is transmitted from a transmit antenna #2, and during the next symbol period, signal S₁ is transmitted from the antenna #1 and a signal S₀* is transmitted from the antenna #2. The signals are spread along a frequency axis for each subcarrier and then transmitted.

Table 1 represents the transmit symbol pattern in case of two transmit antennas. In the Table, C_{i,j} represents a spreading code with a chip length of SF for the all i.

TABLE 1

| | TRANSMIT | TRANSMIT |
|---|---|---|
| | ANTENNA #1 | ANTENNA #2 |
| Time t | ${\sum }_{j = 1}^{J = N} {s}_{0} \cdot {C}_{i , j}$ | ${\sum }_{j = 1}^{J = N} {s}_{1}^{*} \cdot {C}_{i , j}$ |
| Time t + T | ${\sum }_{j = 1}^{J = N} {s}_{1} \cdot {C}_{i , j}$ | ${\sum }_{j = 1}^{J = N} {s}_{0}^{*} \cdot {C}_{i , j}$ |

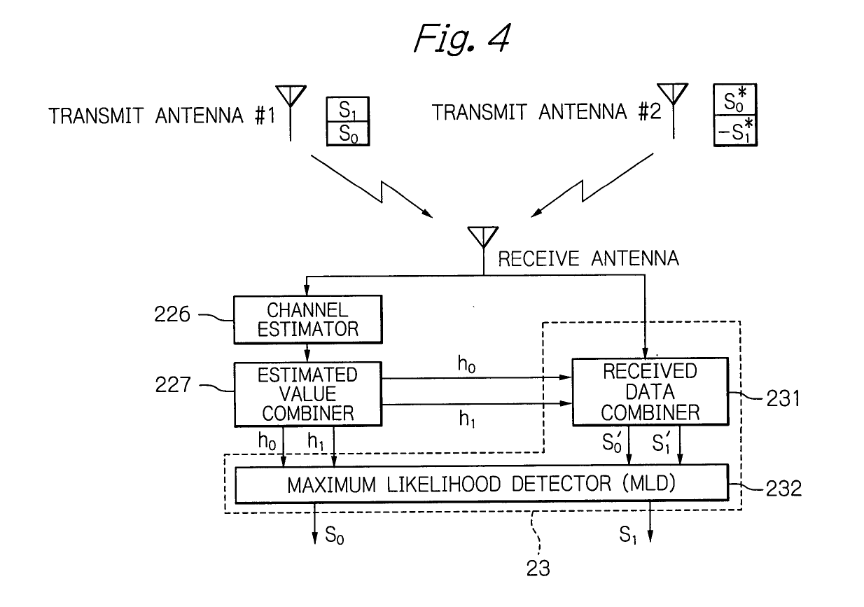

FIG. 4 schematically illustrates a principle configuration of the STTD receiver device according to the present invention.

At the STTD receiver side, if it is assumed that change in propagation channel characteristics is mild, namely fading is constant across two sequential time slots, the channel between the transmit antenna #1 and the receive antenna and the channel between the transmit antenna #2 and the receive antenna are expressed by the following equations (1) and (2), respectively, where j=1, 2, . . . , N.

h₀^{j}(t)=h₀^{j}(t+T)=h₀^{j}=α₀^{j}exp(jθ₀^{j}) (1)

h₁^{j}(t)=h₁(t+T)=h₁^{j}=α₁^{j}exp(jθ₀^{j} (2)

The received signals will be written by the following equations (3) and (4), respectively, where i=1, 2, . . . , Nc/SF, n₀ and n₁ denote complex random variables representing noise and interference, r₀ and r₁ are the received signals at time t and t+T.

r₀^{ij}=r^{ij}(t)=s₀C_{i,j}h₀^{ij}−s₁^{*}C_{i,j}h₁^{ij}+n₀^{ij} (3)

r₁^{ij}=r^{ij}(t+T)=s₁C_{i,j}h₀^{ij}+s₀^{*}C_{i,j}h₁^{ij}+n₁^{ij} (4)

Thus, two time slot signals received by the receive antenna and inverse-spread for the all subcarriers are given by the following equations (5) and (6).

$$\begin{matrix}{r}_{0}^{i} = {r}^{i} ( t ) = {\sum }_{j = 1}^{N} \{ {s}_{0} {C}_{i , j} {h}_{0}^{ij} {C}_{i , j} {h}_{0}^{* ij} - {s}_{1}^{*} {C}_{i , j} {h}_{1}^{ij} {C}_{i , j} {h}_{1}^{* ij} + {n}_{0}^{ij} \} & ( 5 ) \\ {r}_{1}^{i} = {r}^{i} ( t + T ) = {\sum }_{j = 1}^{N} \{ {s}_{1} {C}_{i , j} {h}_{0}^{ij} {C}_{i , j} {h}_{0}^{* ij} + {s}_{0}^{*} {C}_{i , j} {h}_{1}^{ij} {C}_{i , j} {h}_{1}^{* ij} + {n}_{1}^{ij} \} & ( 6 )\end{matrix}$$

The combined signals are represented by the following equations (9) and (10), respectively.

$$\begin{matrix}\hat{{h}_{0}^{i}} = {\sum }_{j = 1}^{N} {\vert {h}_{0}^{ij} \vert}^{2} & ( 7 ) \\ \hat{{h}_{1}^{i}} = {\sum }_{j = 1}^{N} {\vert {h}_{1}^{ij} \vert}^{2} & ( 8 )\end{matrix}$$

r₀ⁱ=rⁱ(t)=ĥ₀ⁱs₀−ĥ₁ⁱs₁^{*} (9)

r₁ⁱ=rⁱ(t+T)=ĥ₀ⁱs₁+ĥ₁ⁱs₁^{*} (10)

Each of the STTD decoder units 23 includes a received data combiner 231 and a maximum likelihood detector (MLD) 232. The received data combiner 231 provides signals S₀ and S₁ expressed by the following equations (11) and (12).

$$\begin{matrix}{s}_{0}^{′} = \hat{{h}_{0}^{{i}^{*}}} {r}_{0}^{i} + \hat{{h}_{1}^{i}} {r}_{1}^{*} & ( 11 ) \\ = \hat{{h}_{0}^{i}} \hat{{h}_{0}^{{i}^{*}} {s}_{0}} + \hat{{h}_{1}^{i}} \hat{{h}_{1}^{{i}^{*}}} {s}_{0} & \\ = ( {\vert \hat{{h}_{0}^{i}} \vert}^{2} + {\vert \hat{{h}_{1}^{i}} \vert}^{2} ) {s}_{0} & \\ {s}_{1}^{′} = \hat{{h}_{0}^{*}} {r}_{1}^{i} - \hat{{h}_{1}} {r}_{0}^{*} & ( 12 ) \\ = \hat{{h}_{0}^{i}} \hat{{h}_{0}^{{i}^{*}} {s}_{1}} + \hat{{h}_{1}^{i}} \hat{{h}_{1}^{{i}^{*}}} {s}_{1} & \\ = ( {\vert \hat{{h}_{0}^{i}} \vert}^{2} + {\vert \hat{{h}_{1}^{i}} \vert}^{2} ) {s}_{1} & \end{matrix}$$

The maximum likelihood detector 232 reconstructs the transmitted data S₀ and S₁ from the output received signals S₀ and S₁ from the data combiner 231 using the output h₀ and h₁ from the estimated value combiner section 227 provided according to the present invention.

The principle of the STTD scheme has been described using a system configuration with two transmit antennas and a single receive antenna. It is apparent that this STTD scheme is easily applicable to a system configuration with M transmit antennas and L receive antennas as shown in FIGS. 1 and 2.

Many widely different embodiments of the present invention may be constructed without departing from the spirit and scope of the present invention. It should be understood that the present invention is not limited to the specific embodiments described in the specification, except as defined in the appended claims.

What is claimed is:

1. A transmitter device adopting space time transmit diversity multicarrier CDMA scheme, comprising:
an encoding interleaving means for encoding transmit data by performing error correction and for interleaving the encoded data;
a mapping means for mapping output signals from said encoding interleaving means to signal points on a conjugate plane;
a serial to parallel conversion means for converting output signals from said mapping means into Nc/SF parallel signals, where Nc is an integer representing the number of points of inverse fast Fourier transform and SF is an integer and a submultiple of Nc;
Nc/SF space time transmit diversity encoding means for encoding in time direction and in space direction the parallel signals from said serial to parallel conversion means;
a plurality of multicarrier CDMA transmit means for respectively copying in parallel output signals from said Nc/SF space time transmit diversity encoding means to SF signals, for respectively spreading copied signals, for respectively performing inverse fast Fourier transform of Nc points with respect to spread signals, and for respectively converting transformed parallel signals into serial signals; and
a plurality of transmit antennas for respectively transmitting output signals from said plurality of multicarrier CDMA transmit means.

2. The transmitter device as claimed in claim 1, wherein said plurality of multicarrier CDMA transmit means comprise means for adding guard intervals to the serial signals, respectively.

3. The transmitter device as claimed in claim 1, wherein each of said plurality of multicarrier CDMA transmit means comprises Nc/SF copier means for respectively copying in parallel output signals from said Nc/SF space time transmit diversity encoding means to SF signals, spreading means for spreading Nc output signals from said Nc/SF copier means by multiplying spreading codes, an inverse fast Fourier transform means for performing inverse fast Fourier transform of Nc points with respect to output signals from said spreading means, a parallel to serial conversion means for converting parallel signals from said inverse fast Fourier transform means into a serial signal, and means for adding a guard interval to the serial signal from said parallel to serial conversion means.

4. The transmitter device as claimed in claim 3, wherein said spreading codes are Walsh Hadamard codes.

5. A receiver device adopting space time transmit diversity multicarrier CDMA scheme, comprising:
a plurality of receive antennas;
a plurality of multicarrier CDMA receive means for respectively converting received signals from said plurality of receive antennas into parallel signals, for respectively performing fast Fourier transform of the converted parallel signals, for respectively inversely spreading transformed signals, and for respectively equalizing and combining inversely spread signals;
space time transmit diversity decoding means for decoding in time direction and in space direction output signals from said plurality of multicarrier CDMA receive means;
a parallel to serial conversion means for converting output signals from space time transmit diversity decoding means into serial signals;
a de-mapping means for de-mapping output serial signals from said parallel to serial conversion means; and
a decoding de-interleaving means for de-interleaving output signals from said de-mapping means and for decoding de-interleaved data by performing error correction.

6. The receiver device as claimed in claim 5, wherein said plurality of multicarrier CDMA receiver means comprise means for removing guard intervals from the received signals, respectively.

7. The receiver device as claimed in claim 5, wherein each of said plurality of multicarrier CDMA receiver means further comprises means for estimating channel for respective subcarriers, and means for respectively equalizing and combining the inversely spread signals in accordance with estimated channels.

8. The receiver device as claimed in claim 5, wherein each of said plurality of multicarrier CDMA receiver means comprises a guard interval removal means for removing a guard interval from the received signal, a serial to parallel conversion means for converting a serial signal from said guard interval removal means into parallel signals, a fast Fourier transform means for performing fast Fourier transform of the parallel signals from said serial to parallel conversion means, inverse spreading means for inversely spreading transformed signals from said fast Fourier transform means by multiplying spreading codes that are the same as spreading codes used in a transmitter device, a channel estimator means for estimating channel for respective subcarriers, and means for respectively equalizing and combining the inversely spread signals from said inverse spreading means in accordance with estimated channels.

9. The receiver device as claimed in claim 8, wherein each of said plurality of multicarrier CDMA receiver means further comprises an estimated value combiner means for combining channel estimated values from said channel estimator means, and wherein said space time transmit diversity decoding means decode output signals from said plurality of multicarrier CDMA receive means by using combined channel estimated values from said estimated value combiner means.

10. The receiver device as claimed in claim 8, wherein said spreading codes are Walsh Hadamard codes.

11. A wireless communication system including a transmitter device and a receiver device adopting space time transmit diversity multicarrier CDMA scheme,
said transmitter device comprising:
an encoding interleaving means for encoding transmit data by performing error correction and for interleaving the encoded data;
a mapping means for mapping output signals from said encoding interleaving means to signal points on a conjugate plane;
a serial to parallel conversion means for converting output signals from said mapping means into Nc/SF parallel signals, where Nc is an integer representing the number of points of inverse fast Fourier transform and SF is an integer and a submultiple of Nc;
Nc/SF space time transmit diversity encoding means for encoding in time direction and in space direction the parallel signals from said serial to parallel conversion means;
a plurality of multicarrier CDMA transmit means for respectively copying in parallel output signals from said Nc/SF space time transmit diversity encoding means to SF signals, for respectively spreading copied signals, for respectively performing inverse fast Fourier transform of Nc points with respect to spread signals, and for respectively converting transformed parallel signals into serial signals; and
a plurality of transmit antennas for respectively transmitting output signals from said plurality of multicarrier CDMA transmit means,
said receiver device comprising:
a plurality of receive antennas;
a plurality of multicarrier CDMA receive means for respectively converting received signals from said plurality of receive antennas into parallel signals, for respectively performing fast Fourier transform of the converted parallel signals, for respectively inversely spreading transformed signals, and for respectively equalizing and combining inversely spread signals;
space time transmit diversity decoding means for decoding in time direction and in space direction output signals from said plurality of multicarrier CDMA receive means;
a parallel to serial conversion means for converting output signals from space time transmit diversity decoding means into serial signals;
a de-mapping means for de-mapping output serial signals from said parallel to serial conversion means; and
a decoding de-interleaving means for de-interleaving output signals from said de-mapping means and for decoding de-interleaved data by performing error correction.

12. The wireless communication system as claimed in claim 11, wherein said plurality of multicarrier CDMA transmit means comprise means for adding guard intervals to the serial signals, respectively.

13. The wireless communication system as claimed in claim 11, wherein each of said plurality of multicarrier CDMA transmit means comprises Nc/SF copier means for respectively copying in parallel output signals from said Nc/SF space time transmit diversity encoding means to SF signals, spreading means for spreading Nc output signals from said Nc/SF copier means by multiplying spreading codes, an inverse fast Fourier transform means for performing inverse fast Fourier transform of Nc points with respect to output signals from said spreading means, a parallel to serial conversion means for converting parallel signals from said inverse fast Fourier transform means into a serial signal, and means for adding a guard interval to the serial signal from said parallel to serial conversion means.

14. The wireless communication system as claimed in claim 13, wherein said spreading codes are Walsh Hadamard codes.

15. The wireless communication system as claimed in claim 11, wherein said plurality of multicarrier CDMA receiver means comprise means for removing guard intervals from the received signals, respectively.

16. The wireless communication system as claimed in claim 11, wherein each of said plurality of multicarrier CDMA receiver means further comprises means for estimating channel for respective subcarriers, and means for respectively equalizing and combining the inversely spread signals in accordance with estimated channels.

17. The wireless communication system as claimed in claim 11, wherein each of said plurality of multicarrier CDMA receiver means comprises a guard interval removal means for removing a guard interval from the received signal, a serial to parallel conversion means for converting a serial signal from said guard interval removal means into parallel signals, a fast Fourier transform means for performing fast Fourier transform of the parallel signals from said serial to parallel conversion means, inverse spreading means for inversely spreading transformed signals from said fast Fourier transform means by multiplying spreading codes that are the same as spreading codes used in said transmitter device, a channel estimator means for estimating channel for respective subcarriers, and means for respectively equalizing and combining the inversely spread signals from said inverse spreading means in accordance with estimated channels.

18. The wireless communication system as claimed in claim 17, wherein each of said plurality of multicarrier CDMA receiver means further comprises an estimated value combiner means for combining channel estimated values from said channel estimator means, and wherein said space time transmit diversity decoding means decode output signals from said plurality of multicarrier CDMA receive means by using combined channel estimated values from said estimated value combiner means.

19. The wireless communication system as claimed in claim 17, wherein said spreading codes are Walsh Hadamard codes.
